(19) United States
(12) Patent Application Publication
(10) Pub. No.: US 2020/0194613 A1
(43) Pub. Date: Jun. 18, 2020

(54) LAYOUT METHOD OF MIXING AND MATCHING LED WAFERS WITH DIFFERENT GRADES AND DISPLAY DEVICE HAVING MIXED AND MATCHED LED WAFERS WITH DIFFERENT GRADES

(71) Applicant: ASTI GLOBAL INC., TAIWAN, Changhua County (TW)

(72) Inventor: CHIEN-SHOU LIAO, New Taipei City (TW)

(21) Appl. No.: 16/576,781

(22) Filed: Sep. 20, 2019

(30) Foreign Application Priority Data
Dec. 17, 2018 (TW) 107145470

(51) Int. Cl. H01L 33/00; H01L 25/075; H01L 27/15; H01L 25/00; H01L 21/66

(52) U.S. Cl. CPC H01L 33/005; H01L 25/0753; H01L 2933/0033; H01L 25/50; H01L 22/12; H01L 27/156

(57) ABSTRACT

A layout method of mixing and matching LED wafers with different grades and a display device having mixed and matched LED wafers with different grades are provided. The layout method of mixing and matching the LED wafers with different grades includes: firstly, providing a plurality of first LED chips and a plurality of second LED chips having different wafer grades from the second LED chips; then, the first LED chips and the second LED chips are alternately disposed on a circuit substrate. The display device includes a circuit substrate, the plurality of first LED chips, and the plurality of second LED chips, the latter two of which have different wafer grades.

### CROSS-REFERENCE TO RELATED PATENT APPLICATION

This application claims the benefit of priority to Taiwan Patent Application No. 107145470, filed on Dec. 17, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a layout method and a display device, and more particularly to a layout method of mixing and matching LED wafers with different grades and a display device having mixed and matched LED wafers with different grades.

### BACKGROUND OF THE DISCLOSURE

Generally, the process of an LED chip is as follows: firstly, a gallium nitride (GaN)-based wafer is formed on the substrate by Metal Organic Chemical Vapor Phase Deposition (MOCVD); commonly used substrates are mainly sapphire, tantalum carbide, tantalum substrates, GaAs, AlN, ZnO and other materials. Then, the two electrodes of an LED PN junction are processed. The electrode processing is also a key process for fabricating the LED wafer, which includes cleaning, evaporation, photolithography, chemical etching, fusion, and grinding. Finally, the wafer is cut by a laser cutter, and the wafer formed after the cutting is tested and sorted to classify each wafer into the different grades.

However, manufacturing the conventional display device uses a wafer of a better grade as one of the materials, and a medium-grade or slightly inferior wafer is excluded from use, thereby causing waste of resources.

### SUMMARY OF THE DISCLOSURE

In response to the above-referenced technical inadequacies, the present disclosure provides a layout method of mixing and matching LED wafers with different grades and a display device having mixed and matched LED wafers with different grades.

In one aspect, the present disclosure provides a layout method of mixing and matching LED wafers with different grades, including: firstly, providing a plurality of first LED chips and a plurality of second LED chips, the first LED chip having a different wafer grade than the second LED chip. Then, the first LED chips and the second LED chips are alternately disposed on a circuit substrate.

In one aspect, the present disclosure provides a layout method of mixing and matching LED wafers with different grades, including: firstly, manufacturing a plurality of LED chips from a same wafer or different wafers. Then, the LED chips are classified into at least a plurality of first LED chips having the same wafer grade and a plurality of second LED chips having the same wafer grade by the electrical characteristic test or the optical characteristic test, wherein the first LED chips have different wafer grade than the second LED chips. Next, the first LED chips and the second LED chips are disposed on the same circuit substrate.

In one aspect, the present disclosure provides a display device having mixed and matched LED wafers with different grades, including: a circuit substrate, a plurality of first LED chips and a plurality of second LED chips.

The first LED chips are respectively disposed on the circuit substrate. The second LED chips are respectively disposed on the circuit substrate. The first LED chips have the same wafer grade, the second LED chips have the same wafer grade, and the first LED chip has a different wafer grade than the second LED chip.

Therefore, one of the beneficial effects of the present disclosure is that, by the technical features of “providing a plurality of first LED chips and a plurality of second LED chips, having different wafer grades” and “alternately disposing the first LED chips and the second LED chips on a circuit substrate,” the layout method of mixing and matching LED wafers with different grades can mix and match different grades of LED chips.

Another beneficial effect of the present disclosure is that, by the technical features of “manufacturing a plurality of LED chips from a same wafer or different wafers,” “classifying the LED chips into at least a plurality of first LED chips having the same wafer grade and a plurality of second LED chips having the same wafer grade by the electrical characteristic test or the optical characteristic test, and the first LED chips having different wafer grade from the second LED chips” and “the first LED chips and the second LED chips disposed on the same circuit substrate,” the layout method of mixing and matching LED wafers with different grades can mix and match different grades of LED chips.

Yet another beneficial effect of the present disclosure is that, by the technical features of “a plurality of first LED chips disposed on the circuit substrate, respectively,” “a plurality of second LED chips disposed on the circuit substrate, respectively” and “the first LED chips having the same wafer grade, the second LED chips having the same wafer grade, and the first LED chip having a different wafer grade from the second LED chip” the display device having mixed and matched LED wafers with different grades can mix and match different grades of LED chips.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a flow chart of a layout method of mixing and matching LED wafers with different grades according to a first embodiment of the present disclosure.

FIG. 2 is a schematic view of a wafer according to the first embodiment of the present disclosure.

FIG. 3 is a schematic diagram of step S105 (a) of the first embodiment of the present disclosure.

FIG. 4 is a schematic diagram of step S105 (a) of the first embodiment of the present disclosure.

FIG. 5 is a flow chart of a layout method of mixing and matching LED wafers with different grades according to a second embodiment of the present disclosure.

FIG. 6 is a schematic view of a wafer according to the second embodiment of the present disclosure.

FIG. 7 is a schematic diagram of step S105 (b) of the second embodiment of the present disclosure.

FIG. 8 is a schematic diagram of step S105 (b) of the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

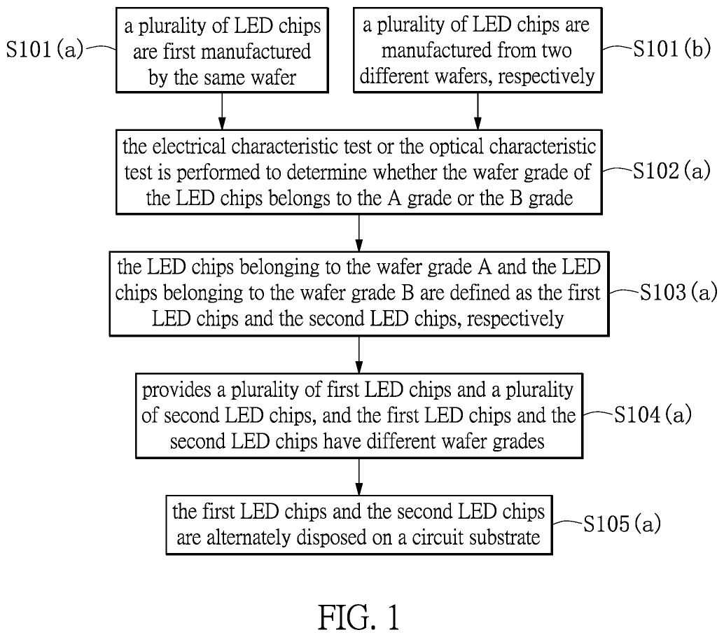

Referring to FIG. 1 to FIG. 4, a first embodiment of the present disclosure provides a layout method of mixing and matching LED wafers with different grades, including at least the following steps.

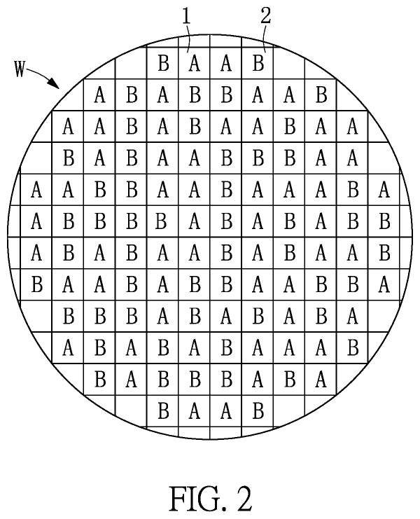

Firstly, as shown in FIG. 1 and FIG. 2, a plurality of first LED chips 1 and a plurality of second LED chips 2 are provided, and the first LED chips 1 and the second LED chips 2 have different wafer grades (step S104 (a)). For example, wafer grades of the first LED chips 1 and the second LED chips 2 can be distinguished according to optical characteristics, electrical characteristics, lifetime, and reliability, and the first LED chips 1 and the second LED chips 2 have different wafer grades. However, the above-mentioned examples are only one of the embodiments and the present disclosure is not limited thereto.

Further, as shown in FIG. 1 and FIG. 2, the layout method of mixing and matching LED wafers with different grades of the present disclosure, before the step S104 (a) of providing the first LED chip 1 and the second LED chips 2, further includes the following steps.

A plurality of LED chips are first manufactured from a same wafer W (step S101 (a)). For example, as shown in FIG. 1 and FIG. 2, the wafer W can be cut to form a plurality of LED wafers having different wafer grades.

Next, the electrical characteristic test or the optical characteristic test is performed to determine whether the wafer grade of the LED chips belongs to the A grade or the B grade (step S102 (a)). For example, as shown in FIG. 1 and FIG. 2, the plurality of LED chips are tested for performance or characteristics to classify, distinguish, and sort the grades of the wafers, thereby determining which wafer grades belong to the grade A, and which wafer grades belong to grade B. LED chip testing can include electrical characteristics testing, optical property testing, and reliability, while electrical property testing can include voltage, current, leakage, antistatic capability, operating voltage, reverse breakdown voltage, power consumption, operating speed, resistance, pressure and so on. Optical property tests may include brightness, luminescence spectral distribution, luminescence center wavelength, color temperature, luminescence intensity, and the like. Reliability testing can include electrostatic sensitivity characteristics, longevity, and environmental characteristics. However, the above-mentioned examples are only one of the embodiments and the present disclosure is not limited thereto.

Next, as shown in FIG. 1 and FIG. 2, the LED chips belonging to the wafer grade A and the LED chips belonging to the wafer grade B are defined as the first LED chips 1 and the second LED chips 2, respectively (step S103 (a)). For example, after the characteristic test of the LED chips cut by the wafer W, the LED chip determined to belong to the wafer grade A can be defined as one of the first LED chips 1, and the LED wafer determined to belong to the wafer grade B can be defined as one of the second LED chips 2. However, the present disclosure is not limited thereto.

In addition, as shown in FIG. 1, the layout method of mixing and matching LED wafers with different grades, before step S104 (a) of providing the first LED chips 1 and the second LED chips 2, may further include the following steps: a plurality of LED chips are manufactured from two different wafers, respectively (step S101(b)); determine the wafer grade of the LED chips to be wafer grade A or wafer grade B by electrical characteristic test or optical characteristic test (step S102(a)); and the LED chips belonging to the wafer grade A and the LED chips belonging to the wafer grade B are defined as first LED chips 1 and second LED chips 2, respectively (step S103(a)). For example, as shown in FIG. 1, the layout method of mixing and matching LED wafers with different grades of the present disclosure may further cut two different wafers to produce the plurality of LED chips (not shown) before step S104 (a). The two wafers can be of different sizes, but the present disclosure is not limited thereto. Then, the LED chips are defined as first LED chips 1 or second LED chips 2 according to the wafer grade.

Finally, as shown in FIG. 1 to FIG. 3, the first LED chips 1 and the second LED chips 2 are alternately disposed on a circuit substrate B (step S105 (a)).

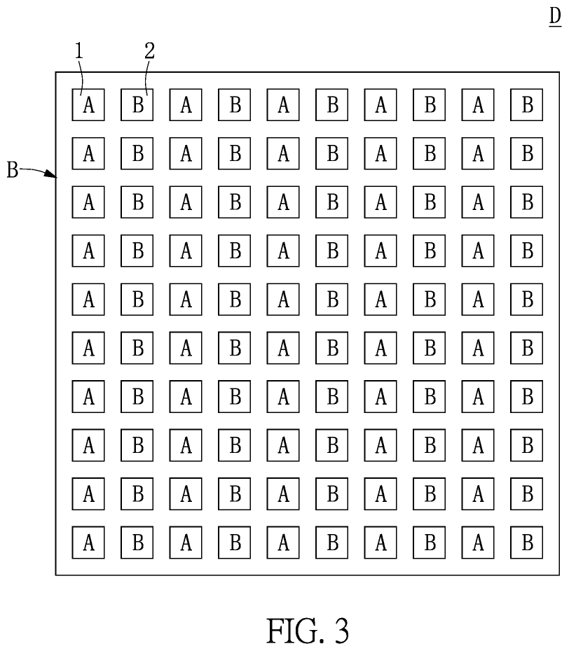

For example, as shown in FIG. 1 to FIG. 3, after the LED chips are respectively defined as first LED chips 1 and second LED chips 2 according to the wafer grade, they may be disposed on the circuit substrate B in an alternating manner, as shown in FIG. 3. However, the present disclosure is not limited thereto. The first LED chip 1 and the second LED chip 2 may be disposed on the circuit substrate B by soldering, bonding, or the like, but the present disclosure is not limited thereto.

Therefore, the layout method of mixing and matching LED wafers with different grades of the present disclosure can be adopted to dispose different grades of LED chips on the circuit substrate B in a mix-and-match manner, and can be used to compensate for the insufficient performance of the second LED chip 2 belonging to the wafer grade B, thereby achieving uniform performance and avoiding waste of resources. Furthermore, the layout method of mixing and matching LED wafers with different grades of the present disclosure can be adopted according to the specific needs of the market or user (such as specific electrical characteristics or specific optical characteristics, but the present disclosure is not limited to this) so as to layout the first LED chips 1 and the second LED chips 2 on the circuit substrate B to generate a display device D that meets the specific requirements.

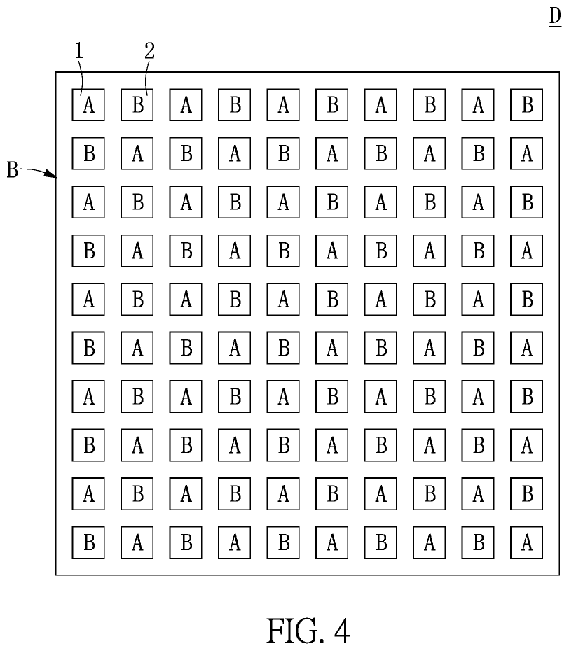

In addition, as shown in FIG. 1 and FIG. 2 to FIG. 4, the layout method of mixing and matching LED wafers with different grades may also be adopted to dispose the first LED chips 1 and the second LED chips 2 on the circuit substrate B in an alternating manner. As shown in FIG. 4. By this manner, the periphery of the second LED chip 2 belonging to the wafer grade B can be surrounded by the first LED chips 1 belonging to the wafer grade A, thereby achieving uniform performance.

Furthermore, referring to FIG. 1 to FIG. 4, the present disclosure further provides a display device having mixed and matched LED wafers with different grades D, including: a circuit substrate B, a plurality of first LED chips 1 and a plurality of second LED chips 2. The first LED chips 1 are respectively disposed on the circuit substrate B. The second LED chips 2 are respectively disposed on the circuit substrate B. The first LED chips 1 have the same wafer grade, the second LED chips 2 have the same wafer grade, and the first LED chip 1 and the second LED chip 2 have different wafer grades. However, the above-mentioned examples are only one of the embodiments and the present disclosure is not limited thereto.

In addition, referring to FIG. 1 to FIG. 4, and according to the technical solution provided by the first embodiment, the present disclosure may further provide a layout method of mixing and matching LED wafers with different grades, which includes the following steps: firstly, a plurality of LED chips are manufactured by the same wafer W or different wafers W. Then, the LED chips are classified into at least a plurality of first LED chips 1 having the same wafer grade and a plurality of second LED chips 2 having the same wafer grade, and the first LED chips 1 have different wafer grade from the second LED chips 2 by electrical characteristic test or optical characteristic test. Finally, the first LED chips 1 and the second LED chips 2 are disposed on the same circuit substrate B. The specific configuration of the layout method of mixing and matching LED wafers with different grades of the present disclosure has been described in the above-described first embodiment; therefore, similar steps will not be repeated herein.

### Second Embodiment

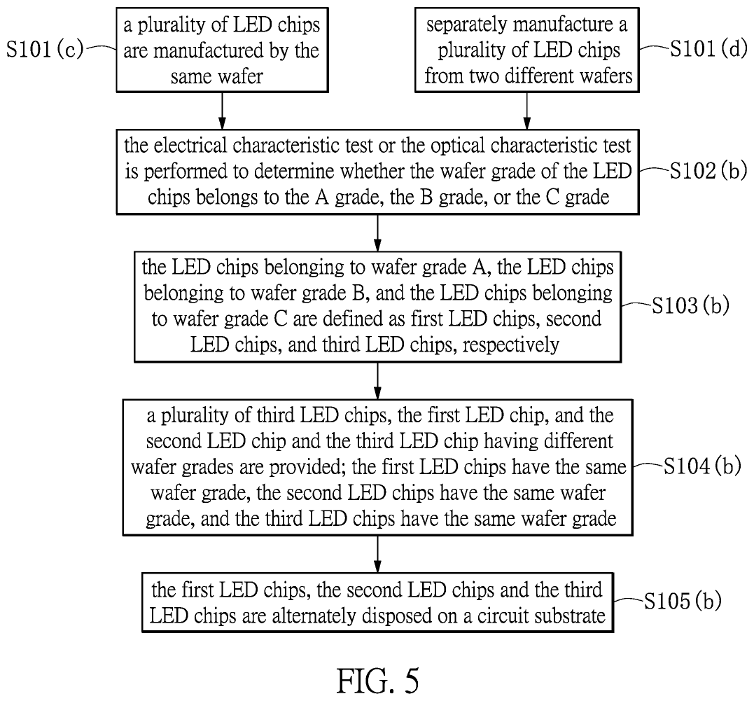

Referring to FIG. 5 to FIG. 8, together with FIG. 1 to FIG. 4, a second embodiment of the present disclosure provides a layout method of mixing and matching LED wafers with different grades that are slightly similar to the layout method of mixing and matching LED wafers with different grades of the first embodiment. Therefore, similar steps will not be repeated herein. Further, according to FIG. 5 to FIG. 8 and FIG. 1 to FIG. 4, the difference between the second embodiment of the present disclosure and the first embodiment is that in the step S104(a) of providing the first LED chip 1 and the second LED chips 2, the layout method further includes the following steps:

A plurality of third LED chips 3, the first LED chip 1, and the second LED chip 2 and the third LED chip 3 having different wafer grades are provided; the first LED chips 1 have the same wafer grade, the second LED chips 2 have the same wafer grade, and the third LED chips 3 have the same wafer grade (step S104 (b)). For example, the third LED chips 3 may be further provided by the layout method of mixing and matching LED wafers with different grades, and the chip grade of the third LED chip 3 is different from that of the first LED chip 1 and the second LED chip 2.

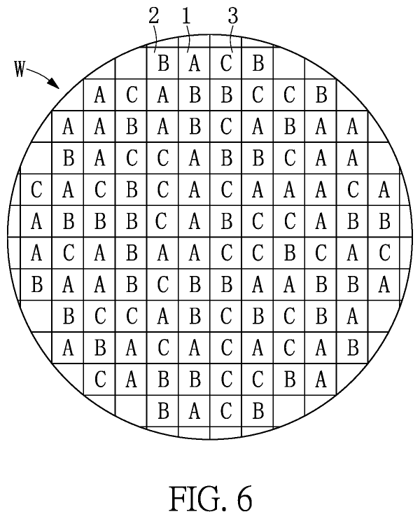

Further, as shown in FIG. 5 and FIG. 6, the layout method of mixing and matching LED wafers with different grades of the present disclosure, before the step S104(b) of providing the first LED chip 1, the second LED chip 2 and the third LED chip 3, the layout method further includes the following steps:

Firstly, a plurality of LED chips are manufactured by the same wafer W (step S101 (c)). For example, as shown in FIG. 6, a wafer W can be cut to form a plurality of LED chips having a plurality of wafer grades therein.

Next, the electrical characteristic test or the optical characteristic test is performed to determine whether the wafer grade of the LED chips belongs to the grades A/B/C (step S102 (b)). LED chip testing can include electrical characteristics testing, optical characteristics testing and reliability. Electrical characteristic tests may include voltage, current, leakage, antistatic capability, operating voltage, reverse breakdown voltage, power consumption, operating speed, and withstand voltage. Optical property tests may include brightness, luminescence spectral distribution, luminescence center wavelength, color temperature, luminescence intensity, and the like. Reliability testing may include electrostatic sensitivity characteristics, longevity, and environmental characteristics. However, the present disclosure is not limited thereto.

Next, the LED chips belonging to wafer grade A, the LED chips belonging to wafer grade B, and the LED chips belonging to wafer grade C are defined as first LED chips 1, second LED chips 2, and third LED chips 3, respectively (step S103 (b)). For example, as shown in FIG. 5 and FIG. 6, after the characteristic test of the LED chips cut by the wafer W, the LED chips determined to belong to the wafer grade A can be defined as the first LED chips 1, the LED chips determined to belong to the wafer grade B can be defined as the first LED chips 2, the LED chips determined to belong to the wafer grade C can be defined as the first LED chips 3. However, the present disclosure is not limited thereto.

In addition, as shown in FIG. 5, before the step S104(b) of providing the first LED chips 1, the second LED chips 2, and the third LED chips 3, the layout method of mixing and matching LED wafers with different grades further includes: respectively manufacturing a plurality of LED chips from two different wafers (step S101(d)); determining the wafer grade of the LED chips by the electrical characteristic test or the optical characteristic test to belong to the grades A/B/C (step S102(b)); and the LED chips belonging to the wafer grade A, the LED chips belonging to the wafer grade B, and the LED chips belonging to the wafer grade C are defined as first LED chips 1, second LED chips 2, and third LED chips 3, respectively (step S103 (b)). For example, as shown in FIG. 5, in the layout method of mixing and matching LED wafers with different grades of the present disclosure, two different wafers (not shown) may further be cut before step S104(b) to produce the plurality of LED chips, and the two wafers can be of different sizes. Next, the LED chips are defined as the first LED chip 1, the second LED chip 2 or the third LED chip 3 according to the wafer grade. However, the present disclosure is not limited thereto.

Finally, as shown in FIG. 5 to FIG. 7, the first LED chips 1, the second LED chips 2 and the third LED chips 3 are alternately disposed on a circuit substrate B (step S105 (b)).

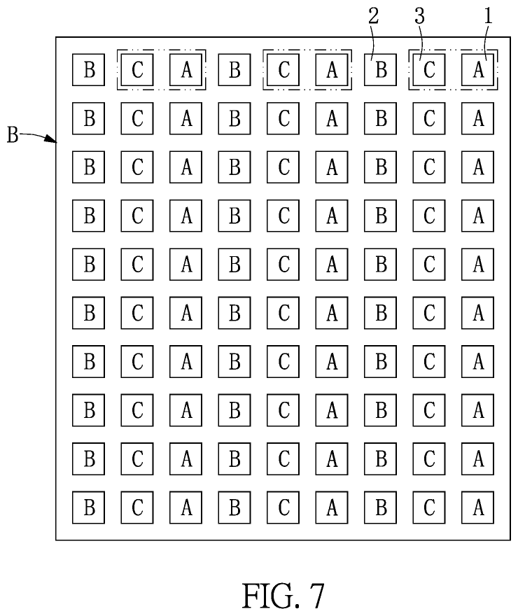

For example, as shown in FIG. 6 and FIG. 7, after the LED chips are defined as the first LED chip 1, the second LED chip 2, and the third LED chip 3 according to the wafer grade, the first LED chips 1, the second LED chips 2, and the third LED chips 3 may be alternately disposed on the circuit substrate B, and the second LED chips 2 may be disposed between the first LED chips 1 and the third LED chips 3.

Therefore, the layout method of mixing and matching LED wafers with different grades of the present disclosure can be used to set different grades of LED chips on the circuit substrate B in a mix-and-match manner, and the first LED chips 1 belonging to wafer grade A can be used to compensate for the insufficient performance (such as brightness or wavelength, but not limited thereto) of the third LED chips 3 belonging to wafer grade C, so that the performance generated by the first LED chips 1 together with the third LED chips 3 (shown in the dashed box in FIG. 7) is similar to that of the second LED chips 2, thereby achieving uniform performance and avoiding waste of resources. Moreover, in the layout method of mixing and matching LED wafers with different grades of the present disclosure, the first LED chips 1, the second LED chips 2 and the third LED chips 3 may also be disposed on the circuit substrate B in a mix-and-match manner according to the specific needs of the market or the user to produce a customized display device D that meets the specific requirements (e.g. specific electrical characteristics or specific optical characteristics, but the present disclosure is not limited thereto).

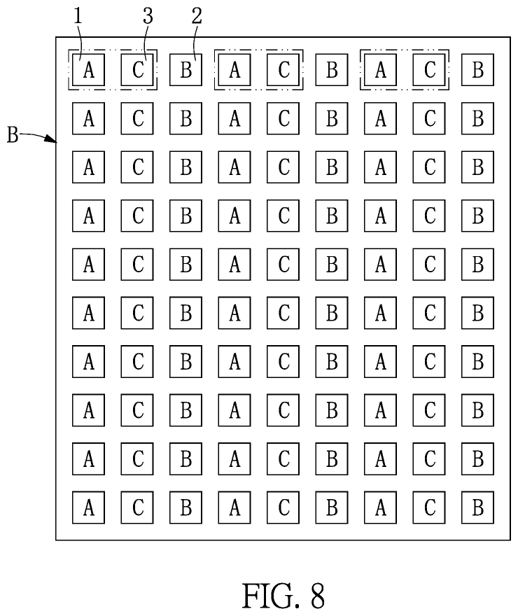

Furthermore, as shown in FIG. 6 and FIG. 8, in the layout method of mixing and matching LED wafers with different grades of the present disclosure, the first LED chip 1, the second LED chip 2, and the third LED chip 3 may also be disposed on the circuit substrate B as shown in FIG. 7. With this method, the first LED chips 1 and the third LED chips 3 can also produce the same performance as the second LED chips 2, thereby achieving uniform performance.

In conclusion, one of the beneficial effects of the present disclosure is that, by the technical features of “providing a plurality of first LED chips 1 and a plurality of second LED chips 2, and the first LED chips 1 and the second LED chips 2 having different wafer grades” and “alternately disposing the first LED chips 1 and the second LED chips 2 on a circuit substrate B,” the layout method of mixing and matching LED wafers with different grades can mix and match different grades of LED chips.

Another beneficial effect of the present disclosure is that, by the technical features of “manufacturing a plurality of LED chips from a same wafer W or different wafers W,” “classifying the LED chips into at least a plurality of first LED chips 1 having the same wafer grade and a plurality of second LED chips 2 having the same wafer grade by the electrical characteristic test or the optical characteristic test, and the first LED chips 1 having different wafer grade than the second LED chips 2” and “the first LED chips 1 and the second LED chips 2 disposed on the same circuit substrate,” the layout method of mixing and matching LED wafers with different grades can mix and match different grades of LED chips.

Yet another beneficial effect of the present disclosure is that, by the technical features of “a plurality of first LED chips 1 disposed on the circuit substrate B, respectively,” “a plurality of second LED chips 2 disposed on the circuit substrate B, respectively” and “the first LED chips 1 having the same wafer grade, the second LED chips 2 having the same wafer grade, and the first LED chip 1 having a different wafer grade than the second LED chip 2” the display device having mixed and matched LED wafers with different grades can mix and match different grades of LED chips.

Further, the layout method of mixing and matching LED wafers with different grades and the display device having mixed and matched LED wafers with different grades have the above-mentioned technical features so as to mix and match LED chips with different wafer grade (e.g. the first LED chips 1 belonging to wafer grade A and the second LED chips 2 belonging to wafer grade B) on the circuit substrate B. The present disclosure can not only achieve the effect of uniform performance, but also solve the problem of resource waste in the related art. Moreover, the first LED chips 1 and the second LED chips 2 may be laid out on the circuit substrate B in a mix-and-match manner according to the specific needs of the market or the user to produce a customized display device D that meets the specific requirements (e.g. specific electrical characteristics or specific optical characteristics, but the present disclosure is not limited thereto).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A layout method of mixing and matching LED wafers with different grades, comprising:
providing a plurality of first LED chips, and a plurality of second LED chips having different wafer grades from the first LED chips; and
alternately disposing the first LED chips and the second LED chips on a circuit substrate.

2. The layout method according to claim 1, wherein before the step of providing the first LED chips and the second LED chips, the layout method further comprising:
manufacturing a plurality of LED chips from a same wafer;
determining wafer grades of the LED chips as wafer grade A or wafer grade B by electrical property test or optical property test; and
defining the LED chip belonging to the wafer grade A and the LED chip belonging to the wafer grade B as the first LED chips and the second LED chips, respectively.

3. The layout method according to claim 1, wherein before the step of providing the first LED chips and the second LED chips, the layout method further comprises:
manufacturing a plurality of LED chips from two different wafers;
determining the wafer grade of the LED chips as grade A or grade B by electrical property test or optical property test; and
defining the LED chip belonging to the wafer grade A and the LED chip belonging to the wafer grade B as the first LED chips and the second LED chips, respectively.

4. The layout method according to claim 1, wherein before the step of providing the first LED chips and the second LED chips, the layout method further comprises: providing a plurality of third LED chips having different wafer grades from the first LED chips and the second LED chips, wherein the first LED chips have the same wafer grade, the second LED chips have the same wafer grade, and the third LED chips have the same wafer grade.

5. The layout method according to claim 4, wherein before the step of providing the first LED chips, the second LED chips and the third LED chips, the layout method further comprises:
manufacturing the plurality of LED chips from a same wafer;
determining the wafer grade of the LED chips as grade A, grade B or class C by electrical property test or optical property test; and
defining the LED chip belonging to the wafer grade A, the LED chip belonging to the wafer grade B, and the LED chip belonging to the grade C wafer grade as the first LED chips, the second LED chips and the third LED chips, respectively.

6. The layout method according to claim 4, wherein before the step of providing the first LED chips, the second LED chips and the third LED chips, the layout method further comprising:
manufacturing the plurality of LED chips from two different wafers;
determining the wafer grade of the LED chips as grade A, grade B or grade C by electrical property test or optical property test; and
defining the LED chip belonging to the wafer grade A, the LED chip belonging to the wafer grade B, and the LED chip belonging to the grade C wafer grade as the first LED chips, the second LED chips and the third LED chips, respectively.

7. The layout method according to claim 4, wherein the first LED chips, the second LED chips, and the third LED chips are alternately disposed along the same direction on the circuit substrate.

8. A layout method of mixing and matching LED wafers with different grades, comprising:
manufacturing a plurality of LED chips from a same wafer or different wafers;
classifying the LED chips into at least a plurality of first LED chips having the same wafer grade and a plurality of second LED chips having the same wafer grade by electrical property test or optical property test, wherein the first LED chips have different wafer grade from the second LED chips; and
disposing the first LED chips and the second LED chips on the same circuit substrate.

9. The layout method according to claim 8, wherein the electrical characteristic test is a voltage or current test, and the optical characteristic test is a brightness or luminescence spectral distribution test.

10. A display device having mixed and matched LED wafers with different grades comprising:
a circuit substrate;
a plurality of first LED chips disposed on the circuit substrate, respectively; and
a plurality of second LED chips disposed on the circuit substrate, respectively;
wherein, the first LED chips have the same wafer grade, and the second LED chips have the same wafer grade, and the first LED chips and the second LED chips have different wafer grades.
